(19) United States
(12) Patent Application Publication
(10) Pub. No.: US 2025/0183860 A1
(43) Pub. Date: Jun. 5, 2025

(54) AMPLIFICATION CIRCUIT

(71) Applicant: RichWave Technology Corp., Taipei (TW)

(72) Inventor: Chia-Wei Hsu, Taipei (TW)

(73) Assignee: RichWave Technology Corp., Taipei (TW)

(21) Appl. No.: 18/544,441

(22) Filed: Dec. 19, 2023

(30) Foreign Application Priority Data
Dec. 1, 2023 (TW) 112146857

(51) Int. Cl. H03F 3/193; H03F 1/32; H03G 1/00

(52) U.S. Cl. CPC H03F 3/193; H03F 1/3205; H03G 1/0023; H03G 1/0088; H03F 2200/451; H03F 2200/61

(57) ABSTRACT

An amplification circuit may include an input terminal, an output terminal, a first amplification path and a second amplification path. The first amplification path may include a first transistor and a second transistor cascoded between the input terminal and the output terminal. The second amplification path may include a third transistor coupled between the input terminal and the output terminal. A control terminal of the first transistor and a control terminal of the third transistor are coupled to the input terminal. A first terminal of the second transistor may be coupled to a second terminal of the first transistor. The first amplification path and the second amplification path may be configured to operate independently of each other. A second terminal of the third transistor and a second terminal of the second transistor are coupled to a common node. In the second amplification path, the transistor closest to the common node is a common-source transistor or a common-emitter transistor.

### CROSS-REFERENCE TO RELATED APPLICATION

This application claims the priority benefit of Taiwan application serial no. 112146857, filed on Dec. 1, 2023. The entirety of the above-mentioned patent application is hereby incorporated by reference herein and made a part of this specification.

### BACKGROUND

### Technical Field

The present disclosure relates to an amplification circuit, and in particular to a multi-gain amplification circuit.

### Description of Related Art

Amplification circuits may be commonly used in various electronics, such as radio frequency circuits. In some applications, a multi-gain amplification circuit may selectively operate in at least one gain mode, such as a high gain mode or a low gain mode, to achieve different levels of amplification for radio-frequency signals. The linearity of an amplification circuit in different gain modes is one of the many important factors considered in the field.

### SUMMARY

The present disclosure may provide an amplification circuit and the amplification circuit may operate in at least one gain mode with desirable linearity.

In some embodiments of the present disclosure, an amplification circuit may include an input terminal, an output terminal, a first amplification path and a second amplification path. The input terminal may be configured to receive a RF signal. The output terminal may be configured to output at least one amplified RF signal. The first amplification path may be coupled between the input terminal and the output terminal. The first amplification path may include a first transistor and a second transistor cascoded. The second amplification path may be coupled between the input terminal and the output terminal and may include a third transistor. A control terminal of the first transistor and a control terminal of the third transistor may be coupled to the input terminal. A first terminal of the second transistor may be coupled to a second terminal of the first transistor. The first amplification path and the second amplification path may be configured to operate independently of each other. A second terminal of the third transistor and a second terminal of the second transistor may be coupled to a common node. In the second amplification path, the transistor closest to the common node is a common-source transistor or a common-emitter transistor.

In some embodiments of the present disclosure, an amplification circuit may include an input terminal, an output terminal, a first amplification path and a second amplification path. The input terminal may be configured to receive a RF signal. The output terminal may be configured to output at least one amplified RF signal. The first amplification path may be coupled between the input terminal and the output terminal, and may comprise M first transistors cascaded. M may be an integer greater than 1. The second amplification path may be coupled between the input terminal and the output terminal, and may comprise N second transistors cascoded. N may be an integer greater than 1 and may be different from M.

Based on the above, the amplification circuit provided in some embodiments of the present disclosure may at least include a first amplification path and a second amplification path, which may be configured to operate independently from each other, to achieve multi-gain modes with improved linearity. In order to make the above-mentioned features and advantages of the present disclosure more obvious and easily understood, embodiments are given below and described in detail with reference to the accompanying drawings.

### BRIEF DESCRIPTION OF THE DRAWINGS

FIG. 1 to FIG. 4 are schematic circuit block diagram of an amplification circuit according to at least one embodiment of the present disclosure.

FIG. 5 is a schematic circuit block diagram of an output matching network according to an embodiment of the present disclosure.

FIG. 6 is a schematic circuit block diagram of an amplification circuit according to another embodiment of the present disclosure.

### DESCRIPTION OF THE EMBODIMENTS

The terms “couple” and “connect” used throughout the specification (including claims) of this disclosure may refer to any direct or indirect connection means. For example, if a first component may be coupled to a second component, it may be interpreted that the first component may be directly coupled to the second component without a third component there-between, or it may also be interpreted that the first component may be indirectly coupled to the second component via at least one other device or component. In addition, the terms “first” and “second” mentioned in the full content of the specification (including claims) of the disclosure are merely used to assist in understanding the contents of the specification of the disclosure, and are not considered to limit the number or the order of the objects described. In addition, wherever possible, components/steps with the same or similar functions or features may be shown by using the same or similar reference numbers, and there descriptions may therefore be omitted.

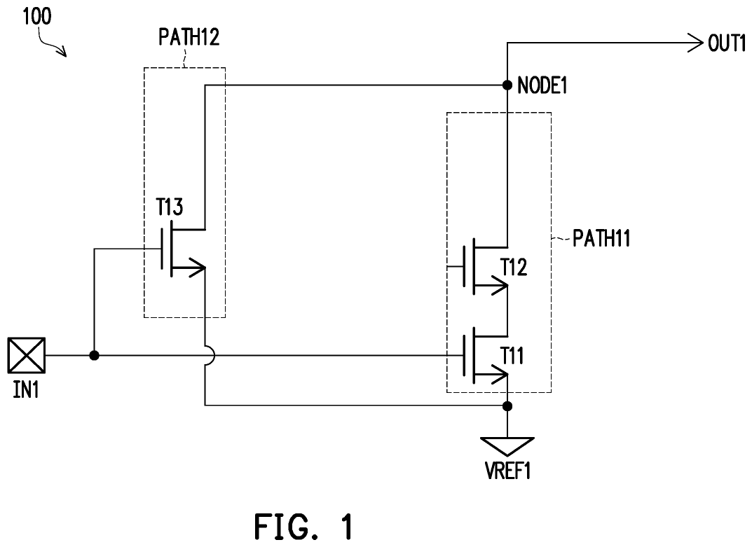

FIG. 1 is a schematic circuit block diagram of an amplification circuit 100 according to an embodiment of the present disclosure. The amplification circuit 100 shown in FIG. 1 may include an input terminal IN1, an output terminal OUT1, a first amplification path PATH11 and a second amplification path PATH12. The input terminal IN1 may be configured to receive a radio-frequency (RF) signal, and the output terminal OUT1 may be configured to output an amplified RF signal. The first amplification path PATH11 may be coupled between the input terminal IN1 and the output terminal OUT1, and may include M transistors cascoded. M may be an integer greater than 1 and may be determined as desired. The second amplification path PATH12 may be coupled between the input terminal IN1 and the output terminal OUT1, and may include N transistors. N may be an integer equal to or greater than 1 and may be determined as desired. In some embodiments, M and N may be different from each other.

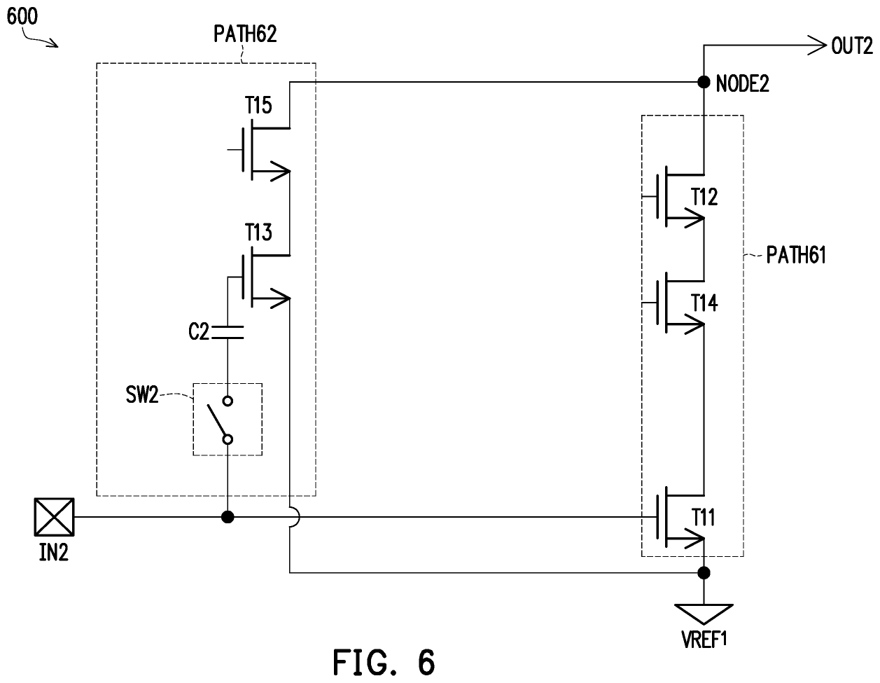

In some embodiments, the first amplification path PATH11 may include a transistor T11 and a transistor T12 that are cascoded, that is, M may be equal to 2. In this embodiment, the transistor T11 and the transistor T12 may respectively include a control terminal, a first terminal, and a second terminal. The control terminal of the transistor T11 may be coupled to the input terminal IN1 to receive a radio-frequency signal. The first terminal of the transistor T11 may be coupled to a reference voltage terminal VREF1, and the second terminal of the transistor T11 may be coupled to the first terminal of the transistor T12. Furthermore, the second terminal of the transistor T12 may be coupled to the output terminal OUT1. However, the present disclosure is not limited thereto, and in other embodiments, M may be an integer greater than 2. For example, the first amplification path PATH11 may also include at least 3 transistors cascoded, which may be further described below with reference to FIG. 6.

In the embodiment shown in FIG. 1, the second amplification path PATH12 may include a transistor T13, that is, N may be equal to 1. In this embodiment, the transistor T13 may include a control terminal, a first terminal, and a second terminal. As for the transistor T13, its control terminal may be coupled to the input terminal IN1, its first terminal may be coupled to the reference voltage terminal VREF1, and its second terminal may be coupled to the output terminal OUT1. In the above embodiment, the second terminal of the transistor T13 and the second terminal of the transistor T12 may be both coupled to a common node NODE1, and the common node NODE1 may further be coupled to the output terminal OUT1. For example, the second terminal of the transistor T13 may be directly coupled to the second terminal of the transistor T12, so as to form the common node NODE1.

In the above embodiment, the level of a reference voltage provided by the reference voltage terminal VREF1 may be determined as desired. For example, a ground voltage or other fixed voltages may be provided by the reference voltage terminal VREF1. In the embodiment described above, the first terminal of the transistor T11 and the first terminal of the transistor T13 may be coupled to the same reference voltage terminal VREF1. However, the present disclosure is not limited thereto, and in other embodiments, the first terminal of the transistor T11 and the first terminal of the transistor T13 may be coupled to different reference voltage terminals respectively.

In some embodiments, the transistor T11, the transistor T12, and/or the transistor T13 may be a field-effect transistor (FET) or a bipolar junction transistor (BJT). In the case of a field effect transistor (FET), the control terminal of the transistor may be the gate, the first terminal may be the source, and the second terminal may be the drain. In such an embodiment, as shown in FIG. 1, the transistor T11 in the first amplification path PATH11 may be, for example, a common-source transistor, and the transistor T12 may be, for example, a common-gate transistor. The transistor T13 in the second amplification path PATH12 may be a common-source transistor, for example. Furthermore, in the case of a bipolar transistor (BJT), the control terminal of the transistor may be the base, the first terminal may be the emitter, and the second terminal may be the collector. In such an embodiment, the transistor T11 in the first amplification path PATH11 may be, for example, a common-emitter transistor, and the transistor T12 may be, for example, a common-base transistor. The transistor T13 in the second amplification path PATH12 may be a common-emitter transistor, for example. However, the present disclosure is not limited thereto, and in other embodiments, the transistor T11, the transistor T12, and/or the transistor T13 may also be implemented by other suitable type of transistors.

In some embodiments, the radio-frequency signal received via the input terminal IN1 may be amplified by the first amplification path PATH11 and/or the second amplification path PATH12, thereby providing at least one amplified RF signal at the output terminal OUT1. In some embodiments, the first amplification path PATH11 and the second amplification path PATH12 may be configured to operate independently from each other. For example, the first amplification path PATH11 and the second amplification path PATH12 may not include a shared transistor. Further, with respect to FIG. 1, in the first amplification path PATH11, the transistor T12 is closer to the common node NODE1 than the transistor T11, and the transistor T12 may be a common gate transistor or a common-base transistor. In the second amplification path PATH12, the transistor T13 may be close to the common node NODE1, and the transistor T13 may be a common source transistor or a common-emitter transistor.

In detail, when the amplification circuit 100 operates in a first gain mode, the first amplification path PATH11 may be turned on and the second amplification path PATH12 may be turned off. The radio-frequency signal may be amplified by the first amplification path PATH11, so as to provide a first amplified RF signal at the output terminal OUT1. In this case, the amplification circuit 100 may provide a first linearity. When the amplification circuit 100 operates in a second gain mode, the first amplification path PATH11 may be turned off and the second amplification path PATH12 may be turned on. The radio-frequency signal may be amplified by the second amplification path PATH12, so as to provide a second amplified RF signal at the output terminal OUT1. In this case, the amplification circuit 100 may provide a second linearity. When the amplification circuit 100 operates in a third gain mode, both the first amplification path PATH11 and the amplification path PATH12 may be turned on. The radio-frequency signal may be amplified by both the first amplification path PATH11 and the amplification path PATH12, so as to provide a third amplified RF signal at the output terminal OUT1. In this case, the amplification circuit 100 may provide a third linearity.

In the embodiment described above, for example, the gain of the first gain mode may be greater than that of the second gain mode, and further, the gain of the third gain mode may be greater than that of the second gain mode. In other words, the second gain mode may be, for example, a low gain mode, the first gain mode may be, for example, a medium gain mode, and the third gain mode may be, for example, a high gain mode. In addition, the second linearity corresponding to the second gain mode may be better than (improved relative to) the first linearity corresponding to the first gain mode, and the third linearity corresponding to the third gain mode may be better than the first linearity corresponding to the first gain mode. However, the present disclosure is not limited thereto, and in other embodiments, various gain mode may be configured such that the third linearity corresponding to the third gain mode may be better than or be comparable to the second linearity corresponding to the second gain mode.

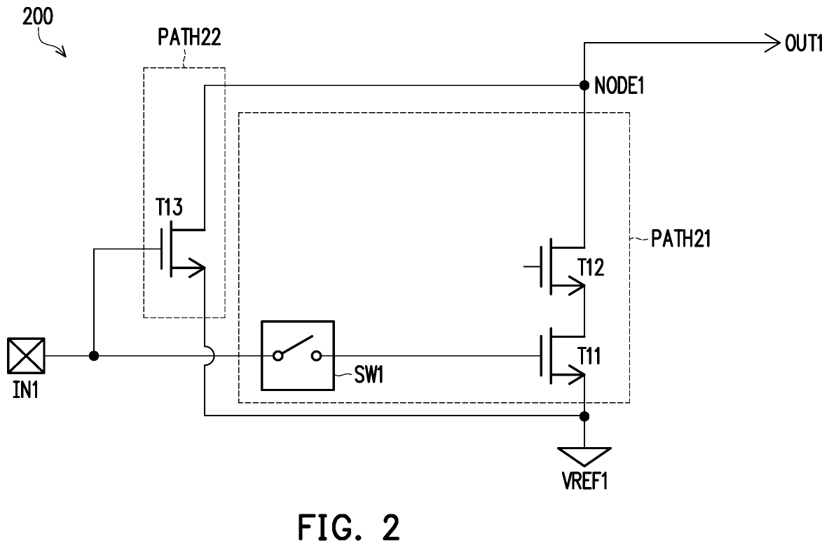

FIG. 2 is a circuit block diagram of an amplification circuit 200 according to another embodiment of the present disclosure. The amplification circuit 200 shown in FIG. 2 may be similar to the amplification circuit 100 shown in FIG. 1 with the difference described below. The first amplification path PATH21 of the amplification circuit 200 may further include a first switching circuit SW1. The first switching circuit SW1 may include a first terminal and a second terminal, the first terminal may be coupled to the input terminal IN1, and the second terminal may be coupled to the control terminal of the transistor T11. The first switching circuit SW1 may be configured to selectively switch on or switch off an electrical connection between the input terminal IN1 and the first amplification path PATH21. For example, when the amplification circuit 200 operates in the first gain mode or the third gain mode, the first switching circuit SW1 may be turned on, so as to electrically connect the input terminal IN1 to the control terminal of the transistor T11. When the amplification circuit 200 operates in the second gain mode, the first switching circuit SW1 may be turned off, so as to electrically disconnect the input terminal IN1 from the control terminal of the transistor T11.

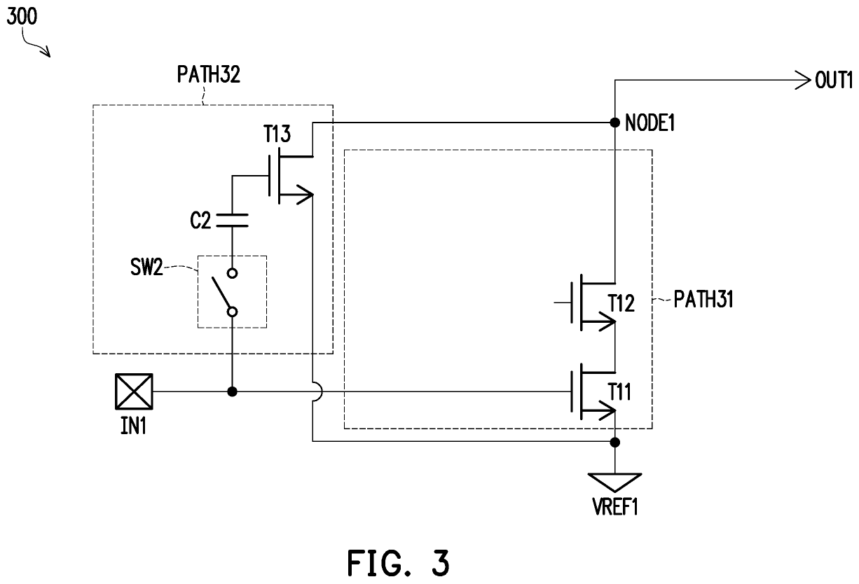

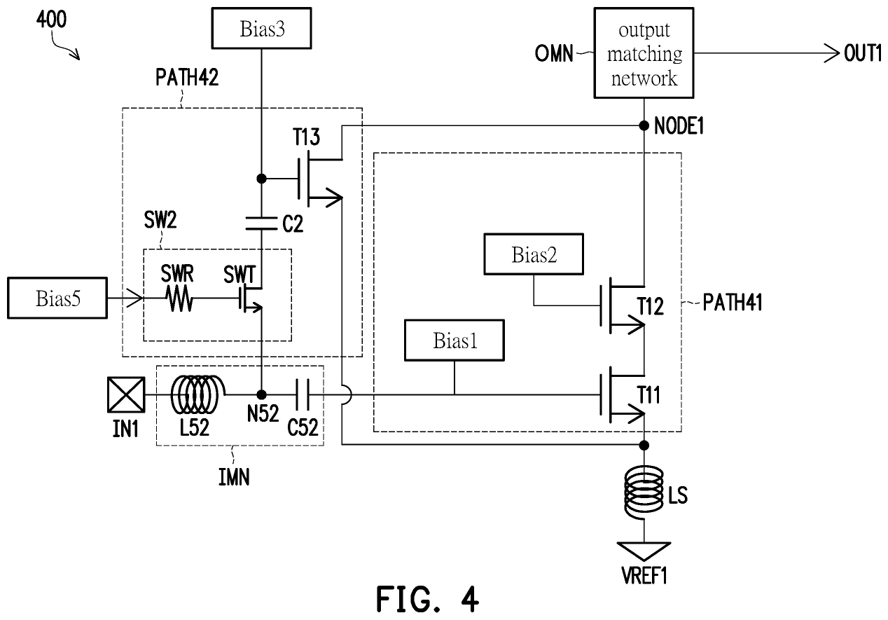

FIG. 3 is a circuit block diagram of an amplification circuit 300 according to another embodiment of the present disclosure. The amplification circuit 300 shown in FIG. 3 may be similar to the amplification circuit 100 shown in FIG. 1. The difference may be that the second amplification path PATH32 of the amplification circuit 300 may further include a second switching circuit SW2 and a capacitor C2. For example, the second switching circuit SW2 and the capacitor C2 may be coupled between the input terminal IN1 and the control terminal of the transistor T13, so as to selectively switch on or switch off the electrical connection between the input terminal IN1 and the second amplification path PATH32. Details of the second switching circuit SW2 may be referred to FIG. 4, and as shown, the second switching circuit SW2 may include a resistor SWR and a switch SWT. The first terminal of the resistor SWR may, for example, be configured to receive a bias signal, such as the fifth bias signal. For example, the switch SWT may include a control terminal, a first terminal, and a second terminal, the control terminal may be coupled to the second terminal of the resistor SWR. The first terminal of the switch SWT may be coupled to the input terminal IN1, and the second terminal of the switch SWT may be coupled to the control terminal of the transistor T13 via the capacitor C2. In this embodiment, the capacitor C2 may be coupled between the switch SWT and the transistor T13, but the disclosure is not limited thereto. In other embodiments, the capacitor C2 may be coupled between the input terminal IN1 and the first terminal of the switch SWT, or the capacitor C2 may be omitted.

In the embodiment described above, for example, when the amplification circuit 300 operates in the first gain mode, the second switching circuit SW2 may be turned off to electrically disconnect the input terminal IN1 from the control terminal of the transistor T13. When the amplification circuit 200 operates in the second gain mode or the third gain mode, the second switching circuit SW1 may be turned on to electrically connect the input terminal IN1 to the control terminal of the transistor T13.

FIG. 4 is a circuit block diagram of an amplification circuit 400 according to another embodiment of the present disclosure. The amplification circuit 400 shown in FIG. 4 may be similar to the amplification circuit 300 shown in FIG. 3 with the difference described below. The amplification circuit 400 may further include at least one bias circuit, an inductor LS, an input matching network IMN and an output matching network OMN.

In the embodiment shown in FIG. 4, the first, second, and third bias circuits Bias1, Bias2, and Bias3 may be coupled to the control terminals of the transistors T11, T12, and T13 respectively, and may be used to provide a first, second, and third bias signal respectively. For example, the first bias circuit Bias1 may be configured to provide the first bias signal, and the transistor T11 may be enabled or disabled according to the first bias signal.

Specifically, when the amplification circuit 400 operates in the first gain mode, the first bias circuit Bias1 may enable the transistor T11, and the second bias circuit Bias2 may enable the transistor T12, so that the first amplification path PATH41 may be turned on. In this case, the third bias circuit Bias3 may disable transistor T13, or the second switching circuit SW2 may be turned off. When the amplification circuit 400 operates in the second gain mode, the third bias circuit Bias3 may enable the transistor T13, and the second switching circuit SW2 may be turned on, such that the second amplification path PATH42 may be turned on. In this case, the first bias circuit Bias1 may disable transistor T11, or the second bias circuit Bias2 may disable transistor T12, so that the first amplification path PATH41 may be turned off. It should be noted that, in other embodiments, the first amplification path PATH41 may be turned off optionally by turning off the first switching circuit SW1 (shown in FIG. 2). In other words, when the amplification circuit 400 operates in the second gain mode, the first amplification path PATH41 may be turned off by at least one of the following: the first bias circuit Bias1 disabling the transistor T11, the second bias circuit Bias2 disabling the transistor T12, or the first switching circuit SW1 (shown in FIG. 2) being turned off. When the amplification circuit 400 operates in the third gain mode, the first bias circuit Bias1 may enable transistor T11, the second bias circuit Bias2 may enable transistor T12, and the third bias circuit Bias3 may enable transistor T13, so that both the first and second amplification paths PATH41 and PATH42 may be both turned on. In this case, the first switching circuit SW1 (if present) and the second switching circuit SW2 (if present) may both be turned on.

In some embodiments, the amplification circuit 400 may further include a fourth bias circuit Bias4 (not shown) and a fifth bias circuit Bias5 (shown in FIG. 4). For example, the fourth bias circuit Bias4 may be coupled to the control terminal of the first switching circuit SW1 (shown in FIG. 2), thereby providing a fourth bias signal, and the first switching circuit SW1 may be turned on or turned off based on the fourth bias signal. Please refer to FIG. 4, the fifth bias circuit Bias5 may be coupled to the second switching circuit SW2, thereby providing a fifth bias signal, and the second switching circuit SW2 may be turned on or turned off based on the fifth bias signal. Specifically, the fifth bias circuit Bias5 may be coupled to the first terminal of the resistor SWR in the second switching circuit SW2.

In the embodiments described above, for the sake of clarity, at least one bias circuit is shown or described. However, the present disclosure is not limited thereto, and in other embodiments, the at least one bias circuit described above may be integrated together.

In some embodiments, as shown in FIG. 4, the amplification circuit 400 may further include an inductor LS. The inductor LS may be coupled between the first terminal of the transistor T11 and the reference voltage terminal VREF1, and may further be coupled between the first terminal of the transistor T13 and the reference voltage terminal VREF1.

In some embodiments, as shown in FIG. 4, the input matching network IMN may be at least partially coupled between the input terminal IN1 and the control terminal of the transistor T11, and may be at least partially coupled between the input terminal IN1 and the control terminal of the transistor T13. For example, the first terminal of the switch SWT of the second switching circuit SW2 may be coupled to a node N52. The input matching network IMN may include an inductor L52 and a capacitor C52, and the node N52 may be disposed between the inductor L52 and the capacitor C52. The inductor L52 may be coupled between the input terminal IN1 and the node N52, and the capacitor C52 may be coupled between the node N52 and the control terminal of the transistor T11. The inductor L52 may be coupled to the control terminal of the transistor T13 via the second switching circuit SW2 and via the capacitor C2. In other embodiments, the locations of the inductor L52 and the capacitor C52 may be interchanged. In some other embodiments, the inductor L52 and the capacitor C52 of the input matching network IMN may be coupled in series between the input terminal IN1 and the node N52.

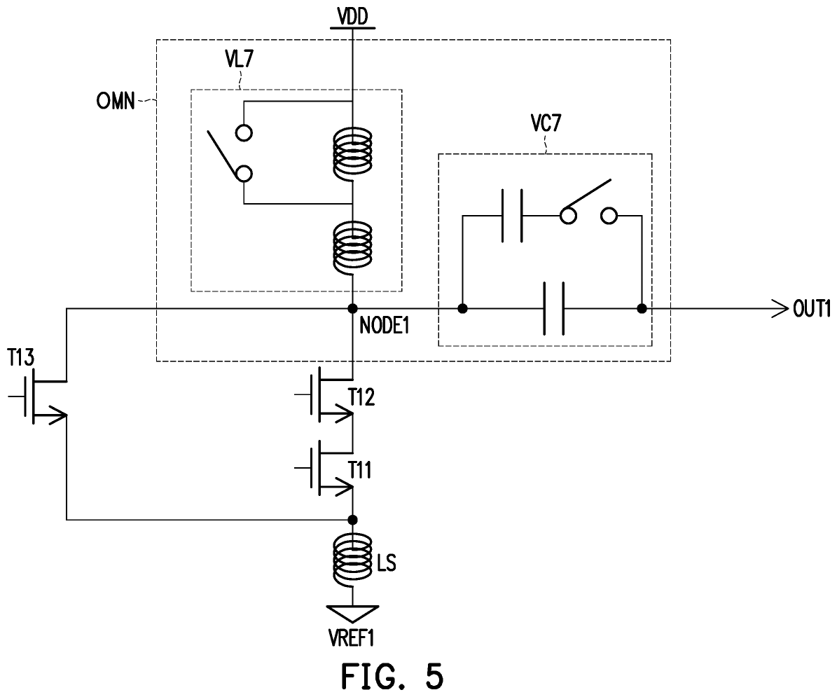

In some embodiments, the output matching network OMN may be coupled between the common node NODE1 and the output terminal OUT1. FIG. 5 is a schematic circuit block diagram of an output matching network according to an embodiment of the present disclosure. In the embodiment shown in FIG. 5, the output matching network OMN may include a variable inductor VL7 and a variable capacitor VC7. The variable inductor VL7 may be coupled between the common node NODE1 and a system voltage terminal VDD, and the variable capacitor VC7 may be coupled between the common node NODE1 and the output terminal OUT1. In this embodiment, the level of a system voltage provided by the system voltage terminal VDD may be determined as desired, such as according to actual design requirements. FIG. 5 merely shows an exemplary embodiment and is not intended to limit the present disclosure.

FIG. 6 is a schematic circuit block diagram of an amplification circuit 600 according to another embodiment of the present disclosure. The amplification circuit 600 may include the first amplification path PATH61 and the second amplification path PATH62. The first amplification path PATH61 may be coupled between the input terminal IN2 and the output terminal OUT2, and may include M transistors cascoded. M is an integer greater than 1 and may be determined as desired. The second amplification path PATH62 may be coupled between the input terminal IN2 and the output terminal OUT2, and may include N transistors cascoded. N is an integer greater than 1 and may be determined as desired. In some embodiments, M and N may be different from each other.

In some embodiments, the first amplification path PATH61 may include the transistor T11, the transistor T14, and the transistor T12 which are cascoded. That is, M may be 3. In this embodiment, the transistor T11, the transistor T14, and the transistor T12 may respectively include a control terminal, a first terminal, and a second terminal. The control terminal of the transistor T11 may be coupled to the input terminal IN2 to receive a radio-frequency signal. The first terminal of the transistor T11 may be coupled to the reference voltage terminal VREF1, and the second terminal of the transistor T11 may be coupled to the first terminal of the transistor T14. The second terminal of the transistor T14 may be coupled to the first terminal of the transistor T12, and the second terminal of the transistor T12 may be coupled to the output terminal OUT2.

In some embodiments, the second amplification path PATH62 may include the transistor T13 and the transistor T15, that is, N may be 2. In this embodiment, the transistor T13 and the transistor T15 may respectively include a control terminal, a first terminal, and a second terminal. The control terminal of the transistor T13 may be coupled to the input terminal IN2, the first terminal may be coupled to the reference voltage terminal VREF1, and the second terminal may be coupled to the first terminal of transistor T15. The second terminal of the transistor T15 may be coupled to the output terminal OUT2. In the embodiment described above, the second terminal of the transistor T15 and the second terminal of the transistor T12 may be coupled to the common node NODE2, and the common node NODE2 may further be coupled to the output terminal OUT2. For example, the second terminal of the transistor T15 may be directly coupled to the second terminal of the transistor T12, so as to form the common node NODE2.

In some embodiments, please refer to FIG. 6, in the first amplification path PATH61, compared with the transistors T11 and T14, the transistor T12 may be located closer to the output terminal OUT2, and the transistor T12 may be a common gate or a common-base transistor. In the second amplification path PATH62, compared with the transistor T13, the transistor T15 may be located closer to the output terminal OUT2, and the transistor T15 may be a common gate or a common-base transistor.

In some embodiments, the first amplification path PATH61 may further include a first switching circuit SW1 (not shown) configured to selectively switch on or switch off the electrical connection between the input terminal IN2 and the first amplification path PATH61. Alternatively or additionally, the second amplification path PATH62 may also include a second switching circuit SW2 configured to selectively switch on or switch off the electrical connection between the input terminal IN2 and the second amplification path PATH62. As shown in FIG. 6, the second switching circuit SW2 and the capacitor C2 may be similar to those described with respect to FIG. 4, and may not be repeated here.

In summary, at least one amplification circuit according to the present disclosure may include at least a first amplification path and a second amplification path, which may be configured to operate independently from each other, to achieve multi-gain modes with improved linearity.

Although the present disclosure has been disclosed above through embodiments, they are not intended to limit the present disclosure. Anyone with ordinary knowledge in the relevant technical field may make some changes and modifications without departing from the spirit and scope of the present disclosure. Therefore, the protection scope of the present disclosure shall be determined by the appended patent application scope.

What is claimed is:

1. An amplification circuit, comprising:
an input terminal configured to receive a radio-frequency (RF) signal;
an output terminal configured to output at least one amplified RF signal;
a first amplification path coupled between the input terminal and the output terminal and comprising a first transistor and a second transistor, wherein the first transistor and the second transistor are cascoded; and
a second amplification path coupled between the input terminal and the output terminal, and comprising a third transistor, wherein,
a control terminal of the first transistor is coupled to the input terminal;
a first terminal of the second transistor is coupled to a second terminal of the first transistor;
a control terminal of the third transistor is coupled to the input terminal;
the first amplification path and the second amplification path are configured to operate independently from each other;
a second terminal of the third transistor and a second terminal of the second transistor are coupled to a common node; and
a transistor closest to the common node in the second amplification path is a common-source transistor or a common-emitter transistor.

2. The amplification circuit as claimed in claim 1, wherein the second terminal of the third transistor is directly coupled to the second terminal of the second transistor.

3. The amplification circuit as claimed in claim 1, wherein a first terminal of the first transistor is coupled to a reference voltage terminal, and a first terminal of the third transistor is coupled to the reference voltage terminal.

4. The amplification circuit as claimed in claim 1, wherein,
when the RF signal is amplified by the first amplification path to generate a first amplified RF signal, the amplification circuit provides a first linearity,
when the RF signal is amplified by the second amplification path to generate a second amplified RF signal, the amplification circuit provides a second linearity, and
when the RF signal is amplified by both the first amplification path and the second amplification path to generate a third amplified RF signal, the amplification circuit provides a third linearity.

5. The amplification circuit as claimed in claim 4, wherein,
the second linearity is better than the first linearity, and the third linearity is better than the first linearity.

6. The amplification circuit as claimed in claim 1, wherein the first amplification path further comprises a first switching circuit configured to selectively switch on or switch off a connection between the input terminal and the first amplification path.

7. The amplification circuit as claimed in claim 6, wherein a first terminal of the first switching circuit is coupled to the input terminal, and a second terminal of the first switching circuit is coupled to the control terminal of the first transistor.

8. The amplification circuit as claimed in claim 1, wherein the second amplification path further comprises a second switching circuit configured to selectively switch on or switch off a connection between the input terminal and the second amplification path.

9. The amplification circuit as claimed in claim 8, wherein a first terminal of the second switching circuit is coupled to the input terminal, and a second terminal of the second switching circuit is coupled to the control terminal of the third transistor.

10. The amplification circuit as claimed in claim 8, wherein the second switching circuit comprises:
a resistor, wherein a first terminal of the resistor is configured to receive a bias signal; and
a switch, wherein a control terminal of the switch is coupled to a second terminal of the resistor, a first terminal of the switch is coupled to the input terminal, and a second terminal of the switch is coupled to the control terminal of the third transistor.

11. The amplification circuit as claimed in claim 1 further comprises:
a first bias circuit coupled to the control terminal of the first transistor, and configured to provide a first bias signal to enable or disable the first transistor;
a second bias circuit coupled to a control terminal of the second transistor, and configured to provide a second bias signal to enable or disable the second transistor; and
a third bias circuit coupled to the control terminal of the third transistor, and configured to provide a third bias signal to enable or disable the third transistor, where,
when the first amplification path is turned on, the first bias signal enables the first transistor, and the second bias signal enables the second transistor;
when the second amplification path is turned on, the third bias signal enables the third transistor; and
when the first amplification path and the second amplification path are both turned on, the first bias signal, the second bias signal and the third bias signal enable the first transistor, the second transistor and the third transistor.

12. The amplification circuit as claimed in claim 7, wherein the first switching circuit further comprises a control terminal, and the amplification circuit further comprises:
a fourth bias circuit coupled to a control terminal of the first switching circuit and configured to provide a fourth bias signal to turn on or turn off the switching circuit.

13. The amplification circuit as claimed in claim 10, further comprises:
a fifth bias circuit coupled to the first terminal of the resistor, and configured to provide the bias signal to turn on or turn off the second switching circuit.

14. The amplification circuit as claimed in claim 1, further comprises:
an input matching network at least partially coupled between the input terminal and the control terminal of the first transistor, and at least partially coupled between the input terminal and the control terminal of the third transistor; and
an output matching network at least partially coupled between the common node and the output terminal,
wherein the output matching network comprises:
a variable inductor coupled between the common node and a system voltage terminal; and
a variable capacitor coupled between the common node and the output terminal.

15. The amplification circuit as claimed in claim 3, further comprises:
an inductor coupled between a first terminal of the first transistor and the reference voltage terminal.

16. The amplification circuit as claimed in claim 1, wherein the first amplification path further comprises a fourth transistor coupled between the first transistor and the second transistor, wherein a first terminal of the fourth transistor is coupled to the second terminal of the first transistor, and a second terminal of the fourth transistor is coupled to the first terminal of the second transistor.

17. An amplification circuit, comprising:
an input terminal configured to receive a RF signal;
an output terminal configured to output at least one amplified RF signal;
a first amplification path coupled between the input terminal and the output terminal, and comprising M first transistors cascoded, wherein M is an integer greater than 1; and
a second amplification path coupled between the input terminal and the output terminal, and comprises N second transistors cascoded, wherein N is an integer greater than 1, and M is different from N.

18. The amplification circuit as claimed in claim 17, wherein a transistor closest to the output terminal in the first amplification path is a common-gate transistor or a common-base transistor, and wherein a transistor closest to the output terminal in the second amplification path is a common-gate transistor or a common-base transistor.

19. The amplification circuit as claimed in claim 17, wherein the first amplification path further comprises a first switching circuit configured to selectively switch on or switch off a connection between the input terminal and the first amplification path.

20. The amplification circuit as claimed in claim 17, wherein the second amplification path comprises a second switching circuit configured to selectively switch on or switch off a connection between the input terminal and the second amplification path.
